(19) United States
(12) Patent Application Publication
(10) Pub. No.: US 2009/0190619 A1
(43) Pub. Date: Jul. 30, 2009

(54) SEMICONDUCTOR LASER PACKAGE

(75) Inventors: Haihua Qi, Granada Hills, CA (US); Bifeng Xiong, Shenzhen (CN); Bin Jiang, Shenzhen (CN); Hong Ma, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Shenzhen Century Epitech Photonics Technology Co. Ltd., Shenzhen (CN)

(21) Appl. No.: 12/363,103

(22) Filed: Jan. 30, 2009

(30) Foreign Application Priority Data
Jan. 30, 2008 (CN) 200820091982.X

(51) Int. Cl. H01S 5/024

(52) U.S. Cl. 372/36

(57) ABSTRACT

The present invention provides a semiconductor laser package including a heat sink, a laser bar with a plurality of lasers on the heat sink, an insulated layer arranged between said heat sink and said laser bar, a solder layer combining said insulated layer with said laser bar, and a clearance crossing said solder layer defined between adjacent lasers.

### CROSS-REFERENCE TO RELATED APPLICATIONS

This non-provisional application claims priority under 35 U.S.C. §119(a) on Patent Application No. 200820091982.X filed in China on Jan. 30, 2008, the entire contents of which are hereby incorporated by reference.

### BACKGROUND OF THE INVENTION

1. Field of the Invention

The invention is related to semiconductor lasers, in particular to a semiconductor laser package.

2. Background

It is hard for a single semiconductor laser to get high output power. Generally, the output power of a single semiconductor laser device is less than 10 W. To get higher semiconductor laser output power, it is allowed to arrange many individual lasers into a one dimensional laser array. To achieve high quality laser beam in a laser array, it is required that the emitters of all lasers must be strictly positioned in the same plane, that is all light emitters cannot be distorted and must be aligned in a straight line. It is proved that the precise alignment of laser chips is extremely difficult during high power laser packing. Conventionally for making high power lasers, manufacturers just simply cut a wafer into a one dimensional laser array during process, which is normally called a laser bar. A laser bar includes many semiconductor lasers and all lasers are naturally on the same plane. Under working condition, these lasers have to be electrically connected in parallel mode because they are in the same bar and are not totally electrically isolated each other. It is obvious that high current is necessary for driving lasers in a bar because of parallel working mode. For example, for a laser bar with 19 lasers, if 1.5V, 2 A current is required to drive a single laser, 1.5V, 38 A current will be necessary to drive the whole laser bar. Higher current needs thicker wire which means bulky size of power supply, resulting in higher cost of manufacture, increased weight and inconvenience to many applications where the size of laser power supplies is critically requested.

### SUMMARY OF THE INVENTION

It is an objective of the present invention to provide a low-cost semiconductor laser package with simple structure against the high cost of lasers caused by large size of power supplies in semiconductor lasers in the existing technologies.

The present invention provides a semiconductor laser package including a heat sink, a laser bar with a plurality of lasers on the heat sink, an insulated layer arranged between said heat sink and said laser bar, a solder layer combining said insulated layer with said laser bar, and a clearance crossing said solder layer defined between adjacent lasers.

In said embodiment, the width of said clearance is less than the width of the adjacent laser.

In another embodiment, said clearance crosses into said insulated layer.

In another embodiment, said clearance crosses through said insulated layer.

In said embodiments, the area of said insulated layer is larger than that of said laser bar.

In said embodiments, said insulated layer is welded on one surface of said heat sink through said solder layer.

In other embodiments, said insulated layer is deposited on one surface of said heat sink by chemical or physical method, and then coat a solder layer on said insulated layer.

In said embodiments, at least two lasers are connected in series through at least one metal wire.

In said embodiments, separate power supply is provided for said laser.

In said embodiments, a metallic electrode is mounted at the joint with the metal wire and said laser.

In said embodiments, a metallic electrode is mounted at the joint with the metal wire and said insulated layer.

Comparing with the conventional technologies, the semiconductor laser package structure in accordance with the present invention defines a clearance between lasers on the laser bar, and power is supplied to lasers connected in series to decrease the current supplied and significantly reduce the power supply size, thus the manufacturing cost is effectively reduced. Meanwhile, the laser beam quality of the laser bar will not be affected, thus bringing great convenience to the application of high power semiconductor lasers.

### BRIEF DESCRIPTION OF THE DRAWINGS

FIG. 1 is a front schematic diagram of a semiconductor laser package in accordance with the present invention, which includes a heat sink, a laser bar, an insulated layer, a solder layer, and a clearance;

FIG. 2 is a front schematic diagram of a semiconductor laser package with a clearance crossing into an insulated layer in accordance with another embodiment of the present invention;

FIG. 3 is a front schematic diagram of a semiconductor laser package with a clearance crossing through an insulated layer in accordance with another embodiment of the present invention;

FIG. 4 is an overview schematic diagram of a semiconductor laser package with lasers connected in series in accordance with the present invention; and

FIG. 5 is an overview schematic diagram of a semiconductor laser package with lasers respectively connecting with power supplies in accordance with the present invention.

### DETAILED DESCRIPTION OF THE INVENTION

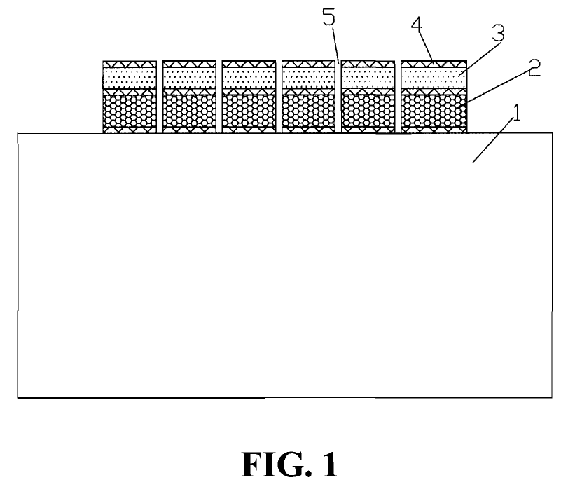

As shown in FIG. 1, a semiconductor laser package in accordance with the present invention comprises a heat sink 1 and a laser bar 3 on the heat sink 1. The laser bar 3 comprises a plurality of lasers 31 positioned in the same plane. An insulated layer 2 is arranged between said heat sink 1 and said laser bar 2. A solder layer 4 is arranged on said insulated layer 2. Said laser bar 3 and said insulated layer 2 are combined together through said solder layer 4. A clearance 5 is defined between adjacent lasers 31 in said laser bar 3. Said clearance 5 crosses into said solder layer 4. In the present invention, through setting said clearance 5 between said lasers 31 on said laser bar 3, said lasers 31 are electrically isolated each other so that said lasers 31 can be connected in series. Through supplying power into said lasers 31 connected in series, the current supplied is decreased and significantly reduce the required power supply dimension, thus the manufacturing cost is effectively reduced for the power supply. Meanwhile, the emitting quality of the laser bar 3 will not be influenced either, bringing great convenience to the application of lasers.

As shown in FIGS. 1-4, the width of said clearance 5 in the present invention is less than that of adjacent laser 31 for ensuring that the operation performance of a single laser 31 will not be influenced by said clearance 4. Two lasers 31 can be electrically connected in series through a metal wire 6. One end of said metal wire 6 is connected with the laser 31; the other end of said metal wire 6 is connected with the insulated layer 2 beneath the adjacent laser 31. With at least one metal wire 6, at least two lasers 31 can be connected in series. By setting a plurality of metal wires 6, lasers 31 to be connected in series can also be multiple.

The number of wires used for connecting lasers depends on the demands for installation. A metallic electrode is installed at each joint with the metal wire 6 and the insulated layer 2. A metallic electrode is installed at each joint with the metal wire 6 and the laser 31. Metallic electrodes are helpful for connection of metal wire 6 with the insulated layer 2 and the laser 31.

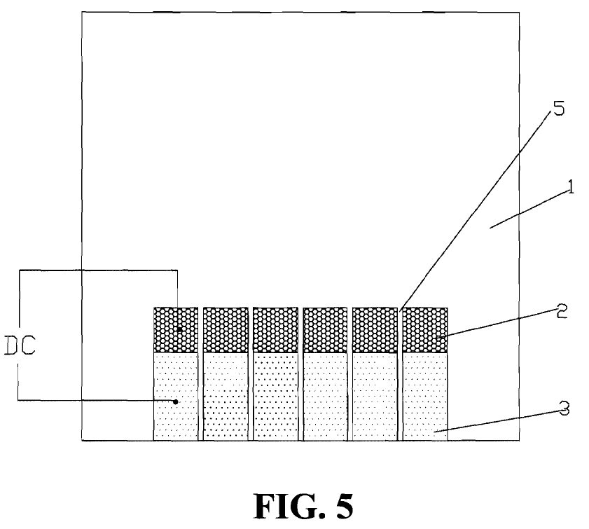

As shown in FIG. 5, separate power supply can be provided for each laser in accordance with some embodiments of the present invention, enabling them to light separately, which depends on different demands from users.

In accordance with some embodiments of the present invention, a laser package can be achieved as follow: integrating a heat sink 1, a heat-conducting insulated layer 2 and a laser bar 3 together, cutting a clearance 5 in said laser bar 3 by physical or chemical methods such as engraving, etching and corrosion. Since the relative positions of the laser bar 3 and the heat sink 1 prior to cutting are fixed and no shift of position of said laser bar 3 will be caused by cutting, and the quality of the output light beam from said laser bar 3 will not be influenced by cutting.

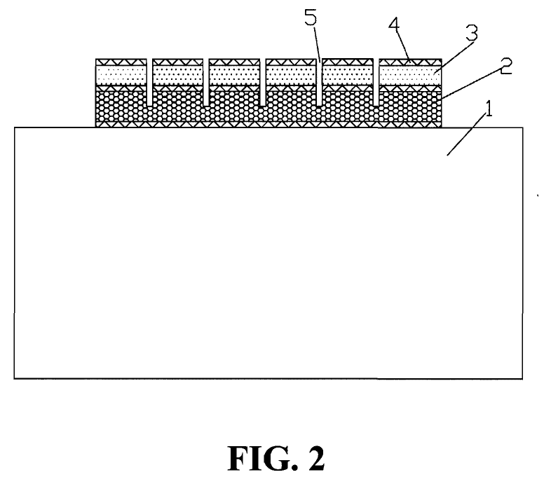

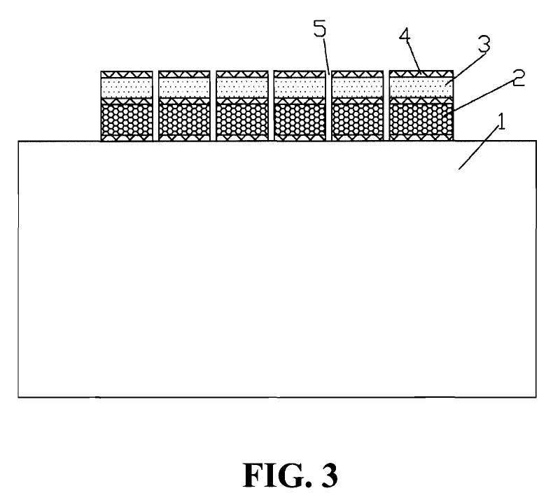

As shown in FIGS. 2 and 3, in semiconductor lasers in accordance with the above-mentioned embodiments of the present invention, clearance 5 can be cut into the insulated layer 2 and also can be cut through the insulated layer 2, thus realizing electrically insulation between lasers 31. It is optimal for said insulated layer to adopt materials with good insulation effect such as AlN and diamond.

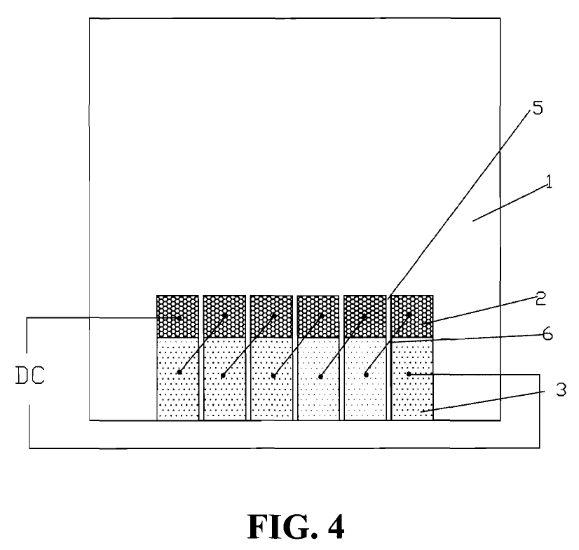

As shown in FIGS. 4 and 5, the area of said insulated layer 2 is larger than that of said laser bar, for the ease of serial connection between lasers. In some other embodiments, the area of insulated layer 2 can be equal to or less than that of the laser bar 3.

As shown in FIGS. 1-3, said insulated layer 2 is welded on the surface of said heat sink 1 through said solder layer 4, in other embodiments, which can also be deposited on the surface of said heat sink by chemical or physical methods and then coat a solder layer on said deposited insulated layer.

What is claimed is:

1. A semiconductor laser package, comprising:
a heat sink,
a laser bar comprising a plurality of lasers on the heat sink,
an insulated layer arranged between said heat sink and said laser bar,
a solder layer combining said insulated layer with said laser bar, and
a clearance crossing said solder layer defined between adjacent lasers.

2. The semiconductor laser package as claimed in claim 1, wherein the width of said clearance is less than the width of the adjacent laser.

3. The semiconductor laser package as claimed in claim 1, wherein said clearance crosses into said insulated layer.

4. The semiconductor laser package as claimed in claim 1, wherein said clearance crosses through said insulated layer.

5. The semiconductor laser package as claimed in claim 1, wherein the area of said insulated layer is larger than that of said laser bar.

6. The semiconductor laser package as claimed in claim 1, wherein said insulated layer is welded on one surface of said heat sink through said solder layer.

7. The semiconductor laser package as claimed in claim 1, wherein said insulated layer is deposited on one surface of said heat sink by chemical or physical method, and then coat a solder layer on said insulated layer.

8. The semiconductor laser package as claimed in claim 1, wherein at least two lasers are connected in series through at least one metal wire.

9. The semiconductor laser package as claimed in claim 8, wherein separate power supply is provided for said laser.

10. The semiconductor laser package as claimed in claim 8, wherein a metallic electrode is mounted at the joint with the metal wire and said laser.

11. The semiconductor laser package as claimed in claim 8, wherein a metallic electrode is mounted at the joint with the metal wire and said insulated layer.
